(19) United States
(12) Patent Application Publication
(10) Pub. No.: US 2013/0273697 A1
(43) Pub. Date: Oct. 17, 2013

(54) FABRICATION METHOD OF A MIXED ALLOY LEAD FRAME FOR PACKAGING POWER SEMICONDUCTOR DEVICES

(71) Applicant: Alpha and Omega Semiconductor Incorporated, Sunnyvale, CA (US)

(72) Inventors: Zhi Qiang Niu, Shanghai (CN); Jun Lu, San Jose, CA (US); Tao Feng, Santa Clara, CA (US)

(21) Appl. No.: 13/914,383

(22) Filed: Jun. 10, 2013

Related U.S. Application Data
(62) Division of application No. 12/652,881, filed on Jan. 6, 2010.

(51) Int. Cl. H01L 21/48

(52) U.S. Cl. CPC H01L 21/4871
USPC 438/122

(57) ABSTRACT

This invention discloses a mixed alloy lead frame for power semiconductor devices, which includes a plurality of heat sinks and a pin array; the heat sinks are made of the first material, with positioning holes on their upper parts and welding zones at the center of their lower parts, while the pin array is made of the second material, which is different from the first material, with a plurality of sets of terminals leading out from its upper end and lower end respectively. The heat sinks are positioned on the lead frame assembly welding plate, the pin is positioned in the area between the upper heat sinks and lower heat sinks on the lead frame assembly welding plate. The mixed alloy lead frame for power semiconductor devices in this invention improves the heat dissipation of lead frame, reduces the fabrication cost of lead frame, and enhances the flexibility of fabrication.

### CROSS REFERENCE TO RELATED APPLICATIONS

This application is a divisional application of a pending US patent application entitled “A MIXED ALLOY LEAD FRAME FOR PACKAGING POWER SEMICONDUCTOR DEVICES AND ITS FABRICATION METHOD” by Zhi Qiang Niu et al with application Ser. No. 12/652,881, Docket#APOM034 and filing date of Jan. 6, 2010 whose content is hereby incorporated by reference for all purposes.

### TECHNICAL FIELD

This invention involves a packaging structure and manufacturing for power semiconductor devices, especially a mixed alloy lead frame for packaging power semiconductor devices and its fabrication method.

### BACKGROUND TECHNOLOGY

The main function of a lead frame is to provide a mechanical supporting carrier for the chip to serve as a conductive medium for connecting IC external circuits and transmitting electric signals, and to dissipate outward the heat generated during chip operation together with the packaging material. Lead frame has become a crucial component in integrated circuit packaging. For power semiconductor devices, which have high power consumption, the heat sinks in the lead frame have become a primary means for improving the chip's heat dissipation performance in the process of packaging.

Chinese Patent Publication No. CN1738012A discloses a method of adding heat sinks to the chip, which includes inputting the chips arranged in an array onto the chip mounter, sucking the array of heat sinks with the multi-head nozzle on the chip mounter, and placing the array of heat sinks on the array of chips, then cutting up the array of heat sinks. This method allows an array of chips to be mounted, thus greatly improves the chip mounting efficiency, but this processing method is complicated and not flexible enough, still unable to quickly solve the large-scale heat dissipation problem of the chip.

In existing technologies, copper alloy lead frames are generally adopted, which are divided into two types. One type is different-gauge copper alloy lead frame, which is molded into one body using a copper alloy of different thickness at the sections of pin and heat sink, and the other type is an identical-gauge copper alloy lead frame, which is molded in one body using a copper alloy of identical thickness at the sections of pin and heat sink. For different-gauge copper alloy lead frame, it is not easy to obtain thick different-gauge copper alloy heat sinks due to limitation of manufacturing means and cost. For identical-profile copper alloy lead frame, the heat dissipation performance is poor and the consumption of plastic packaging material will be increased, due to thin heat sinks. Moreover, both the different-gauge copper alloy lead frame and the identical-gauge copper alloy lead frame are expensive and require high manufacturing cost.

### CONTENTS OF INVENTION

The purpose of this invention is to provide a mixed alloy lead frame for power semiconductor devices and its fabrication method. The mixed alloy lead frame has a high heat capacity ratio, a flexible and a simple manufacturing process, thus saving the processing & fabrication material, and reducing the fabrication cost.

In order to achieve the above goal, the technical scheme of this invention provides a mixed alloy lead frame array for power semiconductor devices comprising:

A plurality of heat sinks and a pin array;

The said heat sinks are made of a first material, with heat sink positioning holes on their upper parts, and heat sink welding zones at the center of their lower parts;

The said pin array is made of the second material, which is different from the first material, set between the upper heat sink and the lower heat sink, with a plurality of sets of pin terminals respectively leading out from the upper end and lower end of the pin array.

The above said mixed alloy lead frame for power semiconductor devices, wherein, the said each heat sink also includes a chip carrier.

The above said mixed alloy lead frame for power semiconductor devices, wherein, the said each set of pin terminals includes three pin terminals, and the pin welding zone corresponding to the heat sink welding zone is set on the middle pin terminal of each set of pin terminals.

The above said mixed alloy lead frame for power semiconductor devices, wherein, a chip carrier is extended from the said each pin welding zone.

The above said mixed alloy lead frame for power semiconductor devices, wherein, the said first material is aluminum alloy.

The above said mixed alloy lead frame for power semiconductor devices, wherein, the said heat sinks are 2mm thick.

The above said mixed alloy lead frame for power semiconductor devices, wherein, the said second material is copper alloy.

A fabrication method of mixed alloy lead frames for packaging power semiconductor devices, characterized in that it includes the following steps:

Step 1. Fabricate a lead frame assembly welding plate, set a plurality of sets of grooves at the upper part and lower part of the lead frame assembly welding plate, set a plurality of heat sink positioning columns in each groove, and set a plurality of pin positioning columns at the center of the lead frame assembly welding plate;

Step 2. Fabricate a plurality of heat sinks, set a positioning hole on the upper part of each heat sink, and set a heat sink welding zone at the center of the lower part of each heat sink;

Step 3. Fabricate a pin array, branch out a plurality of three-pin sets of pin terminals respectively from the upper end and lower end of the pin array, set pin welding zones corresponding to the heat sink welding zones on the middle pin terminal of each set of pin terminals, and set a plurality of pin positioning holes between two sets of pin terminals;

Step 4. Position a plurality of heat sinks in each upper and lower groove of the lead frame assembly welding plate by aligning the heat sink positioning column of the lead frame assembly welding plate through the heat sink positioning hole;

Step 5. Position the pin in the area between the heat sinks disposed within the upper and lower grooves on the lead frame assembly welding plate by aligning the pin positioning column of the lead frame assembly welding plate through the pin positioning hole;

Step 6. Connect the heat sinks and the pins;

Step 7. Remove the connected heat sinks and pins from the lead frame assembly welding plate; clean the heat sinks and pins thus obtaining a lead frame array.

The above said fabrication method, wherein, Step 2 also includes

Step 2.1. Set the chip carrier on the heat sink.

The above said fabrication method, wherein, Step 3 also includes

Step 3.1. Extend the chip carrier from the pin welding zone;

Step 3.2. Fix a chip on the chip carrier;

Step 3.3. Connect the chip to the pin terminal of the pin via the lead.

The above said fabrication method, wherein, Step 2.1 also includes fixing the chip on the chip carrier.

The above said fabrication method, wherein, Step 3 also includes:

Step 3.1. Extend a jumper from the pin terminal.

The above said fabrication method of mixed alloy lead frame for power semiconductor devices, wherein, Step 6 also includes:

Step 6.1. Connect the chip to the pin terminal via the jumper.

The above said fabrication method, wherein, the said method of fixing the chip on the chip carrier is soldering.

A packaging for power semiconductor devices, characterized in that it includes:

A power semiconductor chip, a lead frame and a package, in which the said lead frame includes a heat sink and a set of pins;

The said heat sink is made of the first material, and the said set of pins is made of the second material, which is different from the first material.

The above said packaging for power semiconductor devices, wherein, the said first material is aluminum alloy and the said second material is copper alloy.

The above said packaging for power semiconductor devices, wherein, the said heat sink also includes a chip carrier; and the said chip carrier is made of the first material.

The above said packaging for power semiconductor devices, wherein, the said heat sink also includes a chip carrier; and the said chip carrier is made of the second material.

The above said packaging for power semiconductor devices, wherein, the heat sink welding zone is set on the said heat sink; and the pin welding zone corresponding to the heat sink welding zone is set on the said set of pin terminals.

The above said packaging for power semiconductor devices, wherein, a part of the said package is extended at least to the bottom surface of the heat sink.

The above said packaging for power semiconductor devices, wherein, the said power semiconductor chip includes a plurality of top surface electrodes and a bottom surface electrode, and the said bottom surface electrode is connected with at least one pin terminal, while the said top surface electrode is connected with other pin terminals.

Due to adoption of the above said technical scheme, the mixed alloy lead frame for power semiconductor devices and its fabrication method involved in this invention have the following advantages, compared to the existing technologies.
1. Excellent heat dissipation is achieved due to adoption of aluminum alloy heat sinks with high specific heat.
2. saving plastic packaging material thus reducing the lead frame packaging cost, due to simple fabrication process of aluminum alloy heat sinks that allows the use of thick aluminum alloy heat sinks.
3. Flexible processing and low manufacturing cost, due to adoption of aluminum alloy for heat sinks and copper alloy for pins, which are separately fabricated and then assembled into the mixed alloy lead frame.

### DESCRIPTION OF ATTACHED FIGURES

Refer to the attached figures to better illustrate the implementation examples of this invention. However, the attached figures are only used for description and illustration, without limiting the scope of this invention.

FIG. 1A is the front view of separate components of a mixed alloy lead frame array prior to assembly in Implementation Example 1 of a mixed alloy lead frame for power semiconductor devices and its fabrication method involved in this invention.

FIG. 1B is the side view of separate components of a mixed alloy lead frame array prior to assembly in Implementation Example 1 of a mixed alloy lead frame for power semiconductor devices and its fabrication method involved in this invention.

FIG. 2A is the front view of a lead frame assembly welding plate in Implementation Example 1 of a mixed alloy lead frame for power semiconductor devices and its fabrication method involved in this invention.

FIG. 2B is the side view of a lead frame assembly welding plate in Implementation Example 1 of a mixed alloy lead frame for power semiconductor devices and its fabrication method involved in this invention.

FIG. 3A is the front view of installed heat sinks in Implementation Example 1 of a mixed alloy lead frame for power semiconductor devices and its fabrication method involved in this invention.

FIG. 3B is the side view of installed heat sinks in Implementation Example 1 of a mixed alloy lead frame for power semiconductor devices and its fabrication method involved in this invention.

FIG. 4A is the front view of installed pins in Implementation Example 1 of a mixed alloy lead frame for power semiconductor devices and its fabrication method involved in this invention.

FIG. 4B is the side view of installed pins in Implementation Example 1 of a mixed alloy lead frame for power semiconductor devices and its fabrication method involved in this invention.

FIG. 5A is the front view of a mixed alloy lead frame array in Implementation Example 1 of a mixed alloy lead frame for power semiconductor devices and its fabrication method involved in this invention.

FIG. 5B is the side view of a mixed alloy lead frame array in Implementation Example 1 of a mixed alloy lead frame for power semiconductor devices and its fabrication method involved in this invention.

FIG. 5C is the front view of a mixed alloy lead frame array after plastic package cutting in Implementation Example 1 of a mixed alloy lead frame for power semiconductor devices and its fabrication method involved in this invention.

FIG. 5D is the side view of a mixed alloy lead frame array after plastic package cutting in Implementation Example 1 of a mixed alloy lead frame for power semiconductor devices and its fabrication method involved in this invention.

FIG. 6A is the front view of separate components of a mixed alloy lead frame array prior to assembly in Implementation Example 2 of a mixed alloy lead frame for power semiconductor devices and its fabrication method involved in this invention.

FIG. 6B is the side view of separate components of a mixed alloy lead frame array prior to assembly in Implementation Example 2 of a mixed alloy lead frame for power semiconductor devices and its fabrication method involved in this invention.

FIG. 7A is the front view of a lead frame assembly welding plate in Implementation Example 2 of a mixed alloy lead frame for power semiconductor devices and its fabrication method involved in this invention.

FIG. 7B is the side view of a lead frame assembly welding plate in Implementation Example 2 of a mixed alloy lead frame for power semiconductor devices and its fabrication method involved in this invention.

FIG. 8A is the front view of pins in Implementation Example 2 of a mixed alloy lead frame for power semiconductor devices and its fabrication method involved in this invention.

FIG. 8B is the side view of pins in Implementation Example 2 of a mixed alloy lead frame for power semiconductor devices and its fabrication method involved in this invention.

FIG. 9A is the front view of pins and chips connected via leads in Implementation Example 2 of a mixed alloy lead frame for power semiconductor devices and its fabrication method involved in this invention.

FIG. 9B is the side view of pins and chips connected via leads in Implementation Example 2 of a mixed alloy lead frame for power semiconductor devices and its fabrication method involved in this invention.

FIG. 10A is the front view of installed heat sinks in Implementation Example 2 of a mixed alloy lead frame for power semiconductor devices and its fabrication method involved in this invention.

FIG. 10B is the side view of installed heat sinks in Implementation Example 2 of a mixed alloy lead frame for power semiconductor devices and its fabrication method involved in this invention.

FIG. 11A is the front view of installed pins in Implementation Example 2 of a mixed alloy lead frame for power semiconductor devices and its fabrication method involved in this invention.

FIG. 11B is the side view of installed pins in Implementation Example 2 of a mixed alloy lead frame for power semiconductor devices and its fabrication method involved in this invention.

FIG. 12A is the front view of a mixed alloy lead frame array in Implementation Example 2 of a mixed alloy lead frame for power semiconductor devices and its fabrication method involved in this invention.

FIG. 12B is the side view of a mixed alloy lead frame array in Implementation Example 2 of a mixed alloy lead frame for power semiconductor devices and its fabrication method involved in this invention.

FIG. 12C is the front view of a mixed alloy lead frame array after plastic package cutting in Implementation Example 2 of a mixed alloy lead frame for power semiconductor devices and its fabrication method involved in this invention.

FIG. 12D is the side view of a mixed alloy lead frame array after plastic package cutting in Implementation Example 2 of a mixed alloy lead frame for power semiconductor devices and its fabrication method involved in this invention.

FIG. 13A is the front view of separate components of a mixed alloy lead frame array prior to assembly in Implementation Example 3 of a mixed alloy lead frame for power semiconductor devices and its fabrication method involved in this invention.

FIG. 13B is the side view of separate components of a mixed alloy lead frame array prior to assembly in Implementation Example 3 of a mixed alloy lead frame for power semiconductor devices and its fabrication method involved in this invention.

FIG. 14A is the front view of a lead frame assembly welding plate 3 in Implementation Example 3 of a mixed alloy lead frame for power semiconductor devices and its fabrication method involved in this invention.

FIG. 14B is the side view of a lead frame assembly welding plate 3 in Implementation Example 3 of a mixed alloy lead frame for power semiconductor devices and its fabrication method involved in this invention.

FIG. 15A is the front view of installed heat sinks in Implementation Example 3 of a mixed alloy lead frame for power semiconductor devices and its fabrication method involved in this invention.

FIG. 15B is the side view of installed heat sinks in Implementation Example 3 of a mixed alloy lead frame for power semiconductor devices and its fabrication method involved in this invention.

FIG. 16A is the front view of installed pins in Implementation Example 3 of a mixed alloy lead frame for power semiconductor devices and its fabrication method involved in this invention.

FIG. 16B are respectively the side views of installed pins in Implementation Example 3 of a mixed alloy lead frame for power semiconductor devices and its fabrication method involved in this invention.

FIG. 17A is the front view of a mixed alloy lead frame array in Implementation Example 3 of a mixed alloy lead frame for power semiconductor devices and its fabrication method involved in this invention.

FIG. 17B is the side view of a mixed alloy lead frame array in Implementation Example 3 of a mixed alloy lead frame for power semiconductor devices and its fabrication method involved in this invention.

FIG. 17C is the front view of a mixed alloy lead frame array after plastic package cutting in Implementation Example 3 of a mixed alloy lead frame for power semiconductor devices and its fabrication method involved in this invention.

FIG. 17D is the side view of a mixed alloy lead frame array after plastic package cutting in Implementation Example 3 of a mixed alloy lead frame for power semiconductor devices and its fabrication method involved in this invention.

### SPECIFIC IMPLEMENTATION METHOD

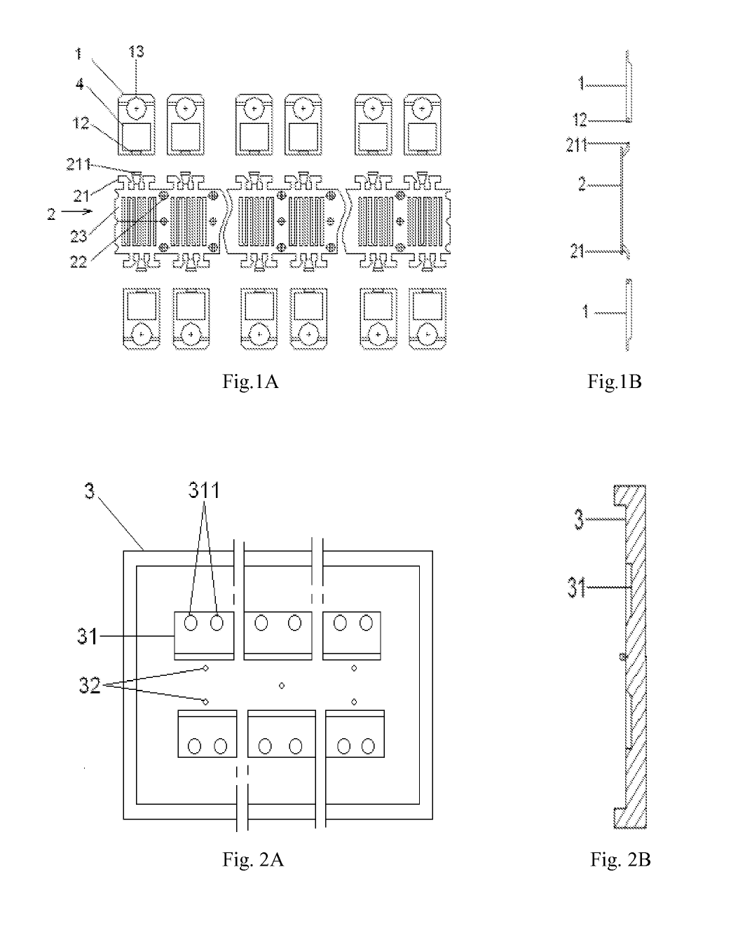

Implementation Example 1: Refer to the attached FIG. 1A and FIG. 1B, which are respectively the front view and side view of separate components of a mixed alloy lead frame array for power semiconductor devices prior to assembly. As shown, the array is formed by a plurality of heat sinks 1 and a plurality of pins constituting a pin array 2; a heat sink positioning hole 13 and a heat sink welding zone 12 are set on each heat sink 1; each heat sink 1 also includes a chip carrier 4; the heat sink 1 is made of aluminum alloy, which has high specific heat capacity, resulting in excellent heat dissipation performance of heat sink. In this implementation example, the optimum thickness of the heat sinks 1 is about 2 mm, the heat sink positioning hole 13 is set on the upper part of the heat sink 1 and the heat sink welding zone 12 is preferably set at the center of the lower part of each heat sink 1. The array of pins 2 is set between upper and lower heat sinks with an upper end and a lower end respectively branching out a plurality sets of pin terminals 21 separated from each other with an offset between the upper and lower ends. Each pin terminal is connected to the entire pin array via a tie bar 23. Pin welding zones 211 corresponding to the heat sink welding zones 12 are set on one pin terminal of each set of pin terminals 21, e.g. the middle pin of a three-pin set as shown, at the upper end and lower end of the array of pins 2. The pin welding zones 211 at the upper end and lower end of the array of pins 2 can be respectively connected with the heat sink welding zones 12 of the upper and lower heat sinks 1. A plurality of pin positioning holes 22 are set in areas between the sets of pin terminals 21. The entire array of pins 2 is made of copper alloy.

The fabrication method of a mixed alloy lead frame array for power semiconductor devices packaging includes the following steps:

Step 1. Referring to the attached FIG. 2A and FIG. 2B, which are respectively the front view and side view of a lead frame assembly welding plate 3, fabricate the lead frame assembly welding plate 3, set a plurality sets of upper and lower grooves 31 at the upper part and lower part of the lead frame assembly welding plate 3 respectively, set a plurality of heat sink positioning columns 311 in each groove 31, and set a plurality of pin positioning columns 32 at the center of the lead frame assembly welding plate 3 between the upper and lower grooves;

Step 2. Referring to the attached FIG. 1A and FIG. 1B, fabricate the heat sink 1, set the positioning hole 13 and the heat sink welding zone 12 on each heat sink 1. The positioning hole 13 is preferably set at the upper part of the heat sink 1 and the heat sink welding zone 12 is preferably set at the center of the lower part of the heat sink 1, set the chip carrier 4 on the heat sink 1; each heat sink 1 can be separated individually, or a plurality of heat sinks can be connected via a tie bar (not shown) according to the pitch of the array of pins 2.

Step 3. Referring to the attached FIGS. 1A and 1B, fabricate the array of pins 2, branch out a plurality - sets of pin terminals 21 respectively from the upper end and lower end of the pin array, set the pin welding zone 211 corresponding to the heat sink welding zone 12 on each set of pin terminals 21, and set a plurality of pin positioning holes 22 between the two sets of pins 21 terminals. In a preferred embodiment, each set of pin terminals 21 includes three pins and the heat sink welding zone 12 is on the middle pin.

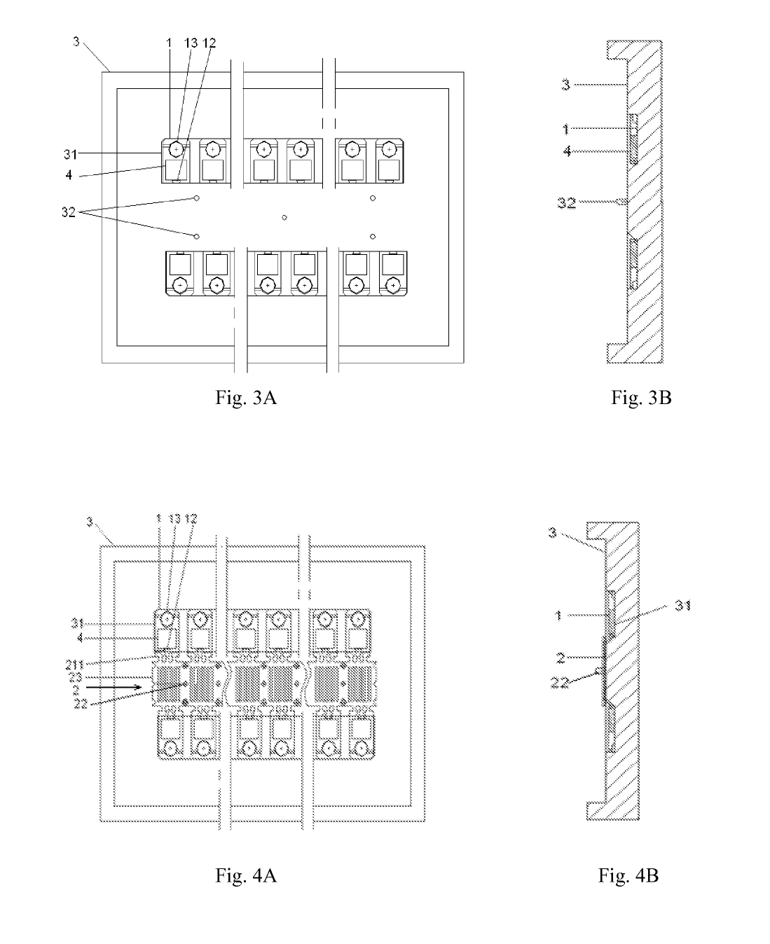

Step 4. Referring to the attached FIG. 3A and FIG. 3B, align the positioning hole 13 of the heat sink 1 through the heat sink positioning column 311 of the lead frame assembly welding plate 3, so that the heat sink 1 is positioned in the groove 31 of the lead frame assembly welding plate 3;

Step 5. Referring to the attached FIG. 4A and FIG. 4B, align the pin positioning hole 22 through the pin positioning column 32 of the lead frame assembly welding plate 3, so that the array of pins 2 is positioned in the area between the upper and lower heat sinks 1 on the lead frame assembly welding plate 3, and the heat sink welding zone 12 matches with the pin welding zone 211;

Step 6. Apply the solder paste to the heat sink welding zone 12 or the pin welding zone 211, connect the heat sinks 1 with the array of pins 2. The solder paste is lead-tin, tin-silver-copper or tin-bismuth alloy, and the welding may be performed in the Nitrogen gas or Nitrogen/Hydrogen gas mixture. Preferably, the welding temperature is 280-520° C., and welding duration is 5-60 seconds. Alternatively, other metal joining methods such as laser welding may be used.

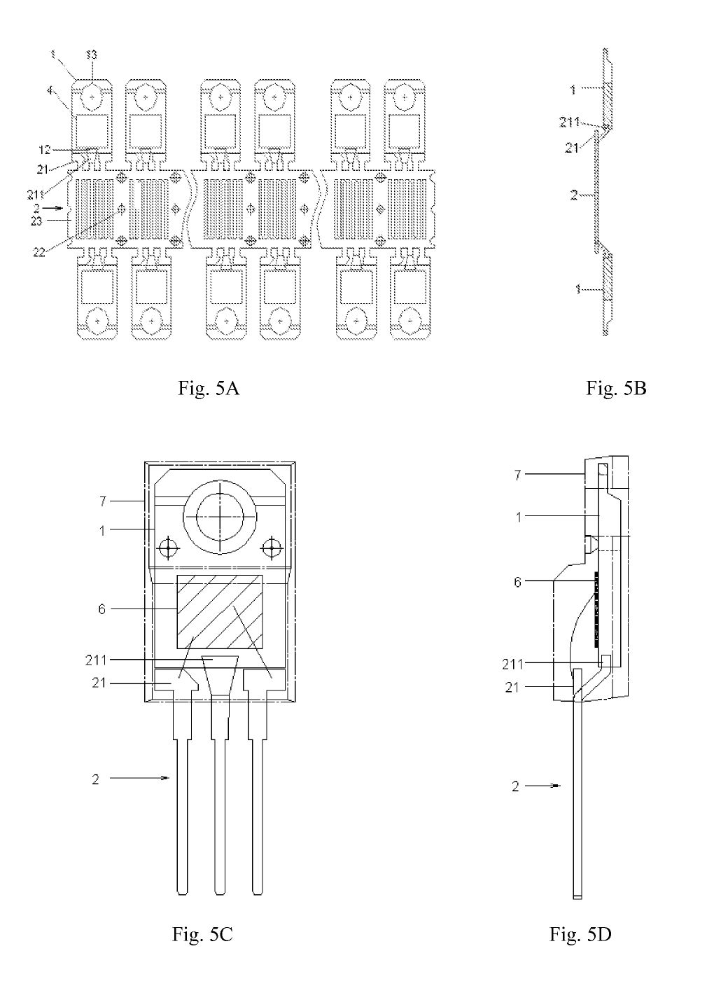

Finally, remove the connected heat sinks 1 and pins 2 from the lead frame assembly welding plate 3 for cleaning and therefore forming the mixed alloy lead frame array as shown in the attached FIG. 5A and FIG. 5B.

The individually packaged semiconductor devices shown in FIG. 5C and FIG. 5D can be formed through cutting for separation of the entire packaged array after the standard semiconductor chip packaging process such as chip adhering, metal wire bonding and plastic molding. Each individually packaged semiconductor device includes a power semiconductor chip 6 (e.g. MOSFET) and a lead frame, in which the power semiconductor chip includes a plurality of top surface electrodes and a bottom surface electrode, and the lead frame includes a thick heat sink made of a low-cost material with good heat dissipation performance (e.g. aluminum alloy) and a plurality of pins made of a material with good electric conductivity (e.g. copper alloy). The heat sink further includes a chip carrier for carrying the semiconductor chip and a pin connection zone for connecting at least one pin of the plurality of pins, and the pin connection zone may be a heat sink welding zone in order to facilitate butting with a pin welding zone on the at least one pin by means of solder, so that the bottom surface electrode of the chip is connected with the at least one pin terminal. The top surface electrode of the chip is connected with other pin terminals via metal wire bonding. In FIG. 5C and FIG. 5D, a portion of plastic package 7 extends at least to the bottom surface of the heat sink, which can be either partially or totally exposed for better heat dissipation. The lead frame for packaging semiconductor devices can use different materials for fabricating the heat sinks and pins respectively, which are then bonded (e.g. welded) together, resulting in good heat dissipation. On the other hand, the heat sinks are independently fabricated and thick heat sinks can be obtained due to the simple process using aluminum alloy, thus saving the plastic packaging material used during the molding process, and greatly reducing the fabrication cost of power semiconductor chip packaging.

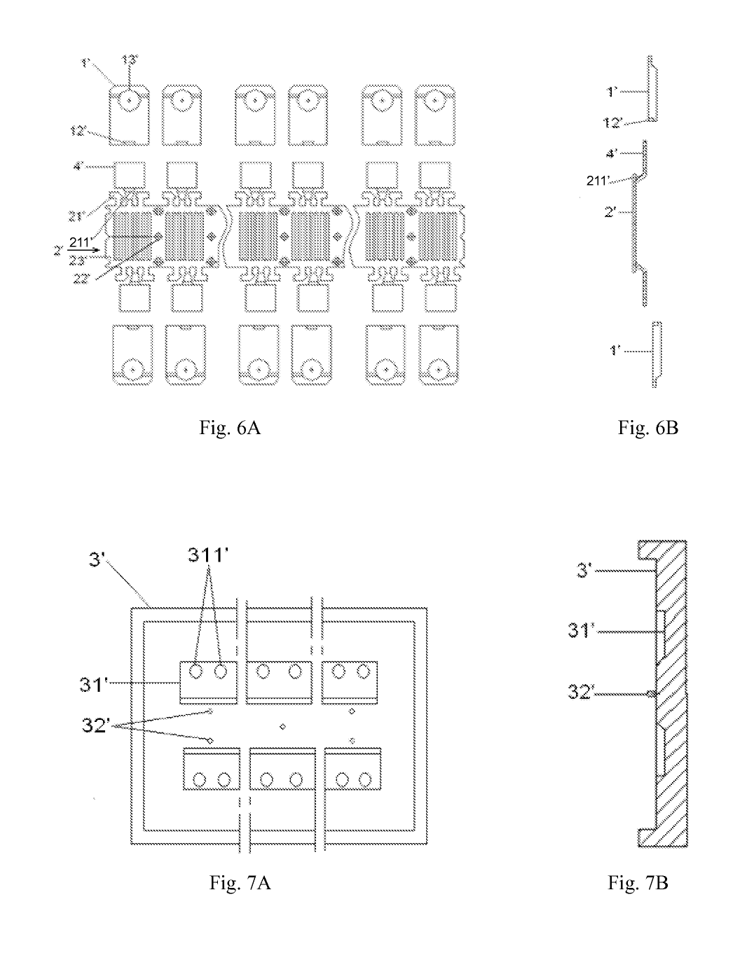

Implementation Example 2: Refer to the attached FIG. 6A and FIG. 6B, which are respectively the front view and side view of separate components of a mixed alloy lead frame array for power semiconductor devices prior to assembly, including a plurality of heat sinks 1′ and an array of pins 2′. As shown, a heat sink positioning hole 13′ is set on the upper part of each of the heat sink 1′, and a heat sink welding zone 12′ is set at the center of the lower part of each heat sink 1′; the heat sink 1′ is made of aluminum alloy and is 2 mm thick; the array of pins 2′ is set between an upper and a lower heat sinks 1′, with an upper end and a lower end respectively branching out a plurality of three-pin sets of pin terminals 21′ separated from each other with an offset between the upper and lower ends. Each pin terminal is connected with the entire pin array via the tie bar 23′. Pin welding zones 211′ corresponding to the heat sink welding zones 12′ are set on the middle pin terminal of each set of three-pin terminals 21′ at the upper end and lower end of the array of pins 2′. The pin welding zones 211′ at the upper end and lower end of the array of pins 2′ can be respectively connected with the heat sink welding zones 12′ of the upper and lower heat sinks 1′. A chip carrier 4′ is extended from each pin welding zone 211′, A plurality of pin positioning holes 22′ are set in areas between the sets of pins 21′. The entire array of pins 2′ is made of copper alloy.

The fabrication of mixed alloy lead frame for power semiconductor devices packaging may include the following steps:

Step 1. Referring to the attached FIG. 7A and FIG. 7B, fabricate a lead frame assembly welding plate 3′, set a plurality of grooves 31′ at the upper part and lower part of the lead frame assembly welding plate 3′, set several heat sink positioning columns 311′ in each groove 31′, and set a plurality of pin positioning columns 32′ at the center of the lead frame assembly welding plate 3′;

Step 2. Referring to the attached FIG. 6A and FIG. 6B, fabricate the heat sink 1′, set a positioning hole 13′ and a heat sink welding zone 12′ on each heat sink 1′. The positioning hole 13′ is preferably set at the upper part of the heat sink 1′ and the set the heat sink welding zone 12′ is preferably set at the center of the lower part of the heat sink 1′;

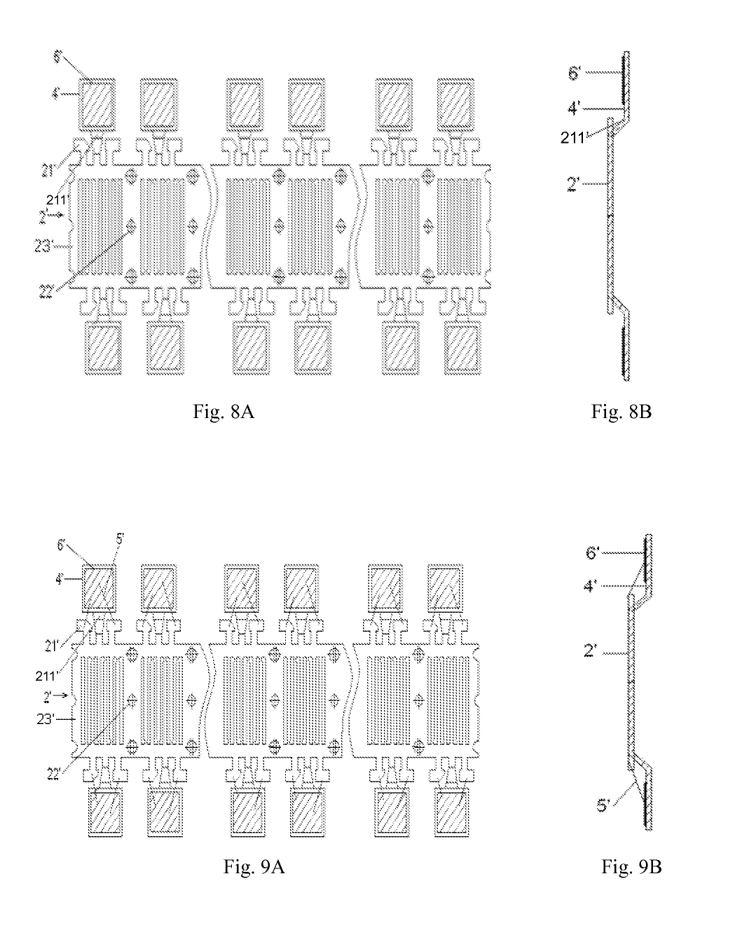

Step 3. Referring to the attached FIG. 7A, FIG. 7B, FIG. 8A, FIG. 8B, FIG. 9A and FIG. 9B, fabricate the arrays of pins 2′, branch out a plurality sets of pin terminals 21′ respectively from the upper end and lower end of the arrays of pins 2′, set the pin welding zone 211′ corresponding to the heat sink welding zone 12′ each set of pin terminals 21′, and set a plurality of pin positioning holes 22′ between two arrays of pins 2′. In a preferred embodiment, each set of pin terminals 21′ includes three pins and the heat sink welding zone 12′ is on the middle pin.

Step 3 also includes:

Step 3.1. provide the chip carrier 4′ as an extension from the pin welding zone 211′; or alternatively the pin welding may extend to at least a portion of the bottom surface of the chip carrier 4′.

Step 3.2. In the Nitrogen gas or Nitrogen/Hydrogen gas mixture, apply lead-tin, tin-silver-copper or tin-bismuth solder paste to the chip carrier 4′, and adhere the chip 6′ onto the chip carrier 4′. Preferably, the welding temperature is 280-520° C., and welding duration is 5-60 seconds;

Step 3.3. Electrically connect electrodes on chip 6′ to the pin terminal 21′ of the arrays of pins 2′ via metal connections 5′.

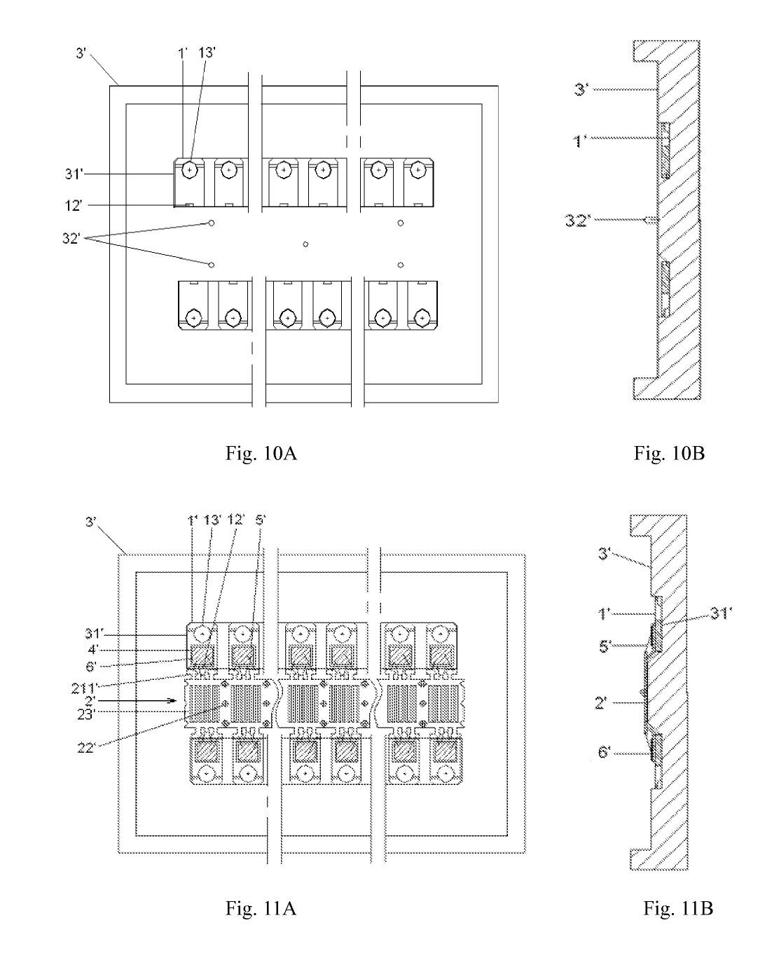

Step 4. Referring to the attached FIG. 10A and FIG. 10B, align the heat sink positioning hole 13′ through the heat sink positioning column 311′ of the lead frame assembly welding plate 3′, so that the heat sink 1′ is positioned in the groove 31′ of the lead frame assembly welding plate 3′; each heat sink 1′ can be separated individually, or a plurality of heat sinks can be connected via the tie bar according to the pitch of the array of pins 2′ (not displayed).

Step 5. Referring to the attached FIG. 11A and FIG. 11B, align the pin positioning hole 22′ through the pin positioning column 32′ of the lead frame assembly welding plate 3′, so that the pin 2′ is positioned in the area between the upper and lower heat sinks 1′ on the lead frame assembly welding plate 3′, and the heat sink welding zone 12′ matches with the pin welding zone 211′;

Step 6. Apply solder paste to the heat sink welding zone 12′ and the pin welding zone 211′, connect the heat sinks 1′ with the arrays of pins 2′ so that the bottom surface electrode of the chip 6′ is connected with the middle pin terminal of the set of pin terminals 21′. Preferably, the lower surface of the chip carrier 4′ can have close contact with the upper surface of the heat sink 1′ or they can be connected by solder in order to enhance the effect of heat dissipation;

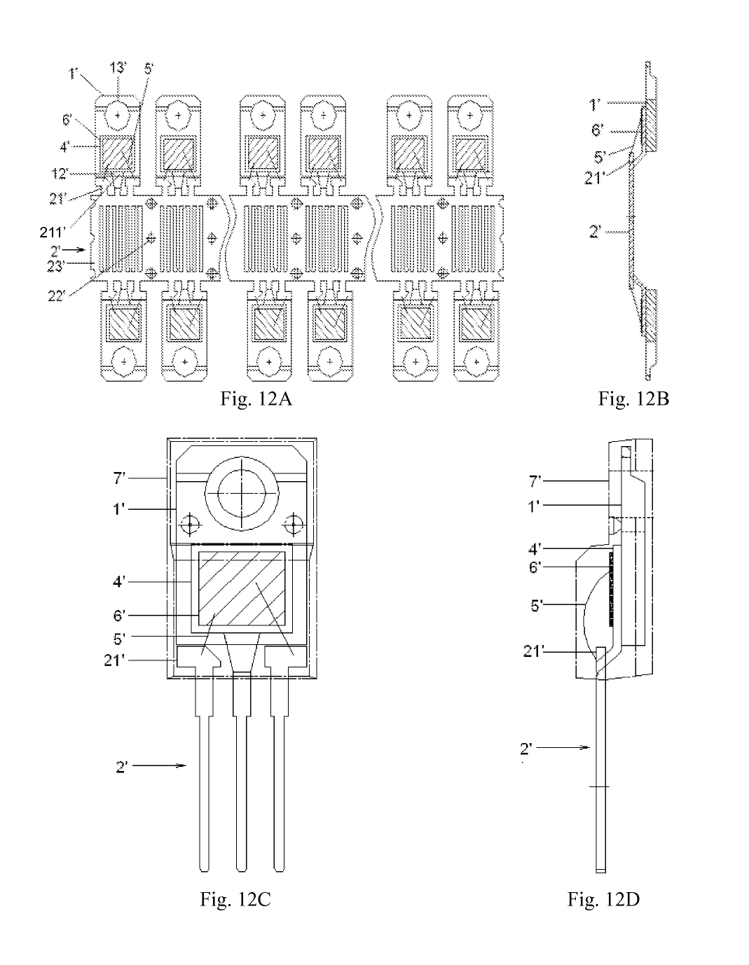

Finally, remove the connected heat sinks 1′ and the arrays of pins 2′ from the lead frame assembly welding plate 3′ for cleaning and therefore obtain the mixed alloy lead frame array with chip connection as shown in the attached FIG. 12A and FIG. 12B.

After plastic molding, the entire packaged array is cut and separated to form individually packaged semiconductor devices as shown in FIG. 12C and FIG. 12D. Each individually packaged semiconductor device includes a power semiconductor chip (e.g. MOSFET) and a lead frame, in which the power semiconductor chip includes a plurality of top surface electrodes and a bottom surface electrode, and the lead frame includes a heat sink made of a low-cost material with good heat dissipation performance (e.g. aluminum alloy) and a plurality of pins made of a material with good electrical conductivity (e.g. copper alloy). The heat sink further includes a pin connection zone for connecting at least one pin of the plurality of pins, and the pin connection zone can be a heat sink welding zone in order to facilitate butting with a pin welding zone on the at least one pin by means of solder. The lead frame further includes a chip carrier for carrying the semiconductor chip, which is connected to the at least one pin and made of the same material as the pin. The lower surface of the chip carrier has close contact with the upper surface of the heat sink or they are connected by solder in order to enhance the effect of heat dissipation. The top surface electrodes of the said chip are connected to other pin terminals via metal connections. In FIG. 12C and FIG. 12D, plastic package 7′ is extended at least to the bottom surface of the heat sink, which can be either partially or totally exposed for better heat dissipation.

The lead frame for packaging semiconductor devices use different materials for fabricating the heat sinks and pins respectively, which are then welded together, resulting in good heat dissipation. On the other hand, the heat sinks are independently fabricated and thick heat sinks can be obtained due to the simple process using aluminum alloy, thus saving the plastic packaging material used during the molding process, and greatly reducing the fabrication cost of power semiconductor chip packaging. The fabrication process is very convenient, in which the chips 6′ are installed and connected with the arrays of pins 2′ at the same time as the arrays of pins 2′ are fabricated.

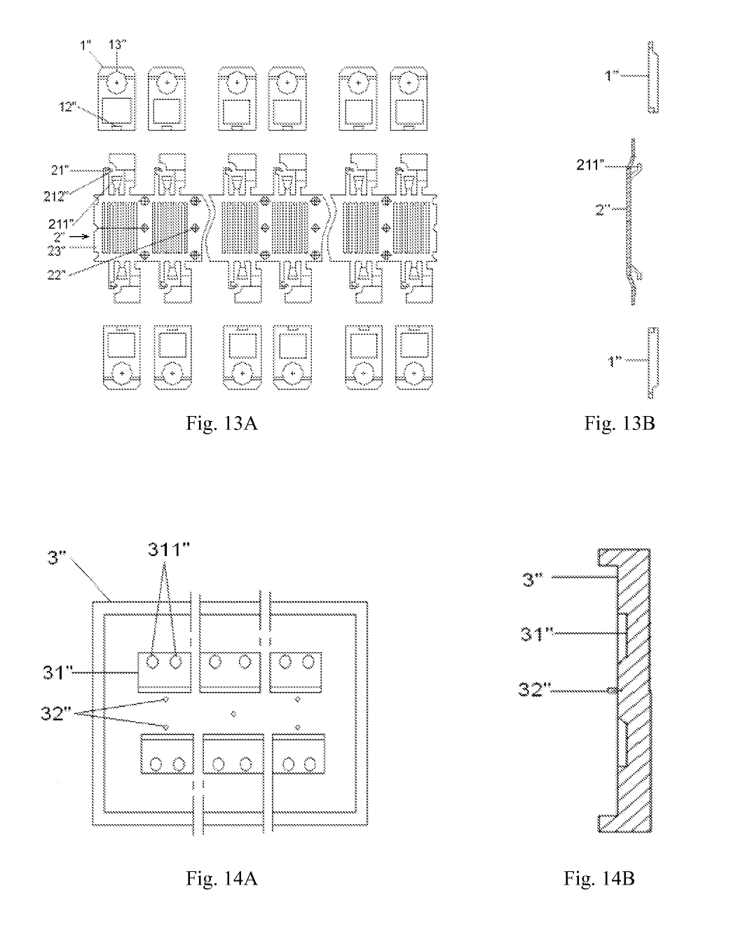

Implementation Example 3: Refer to the attached FIG. 13A and FIG. 13B, which are respectively the front view and side view of separate components of mixed alloy lead frame array for power semiconductor devices prior to assembly, including a plurality of heat sinks 1″ and an array of pins 2″. A heat sink positioning hole 13″ is set on the upper part of each heat sink 1″, and a heat sink welding zone 12″ is set at the center of the lower part of each heat sink 1″. Each heat sink 1″ also includes a chip carrier 4″. The heat sinks 1″ are made of aluminum alloy, and are preferably 2mm thick; the array of pins 2″ is set between the upper and lower heat sinks 1″, with the upper end and lower end respectively branching out a plurality of three-pin sets of pin terminals 21″ separated from each other, and each pin terminal is connected with the entire pin array via a tie bar 23″. Pin welding zones 211″ corresponding to the heat sink welding zones 12″ are set on the middle pin terminal of each set of three-pin terminals 21″ at the upper end and lower end of the array of pins 2″. The pin welding zones 211″ at the upper end and lower end of the array of pins 2″ can be respectively connected with the heat sink welding zones 12″ of the upper and lower heat sinks 1″. Pluralities of pin positioning holes 22″ are set in the areas between the sets of pin terminals 21″. A jumper 212″ is extended from a pin terminal 21″, and the array of pins 2″ is made of copper alloy.

The above fabrication method of mixed a alloy lead frame for power semiconductor devices and the device packaging method include the following steps:

Step 1. Referring to the attached FIG. 14A and FIG. 14B, fabricate the lead frame assembly welding plate 3″, set a plurality of grooves 31″ at the upper part and lower part of the lead frame assembly welding plate 3″, set several heat sink positioning columns 311″ in each groove 31″, and set a plurality of pin positioning columns 32″ at the center of the lead frame assembly welding plate 3″;

Step 2. Referring to the attached FIG. 13A and FIG. 13B, fabricate the heat sink 1″, set a heat sink positioning hole 13″ and a heat sink welding zone 12″ on each heat sink 1″. The positioning hole 13″ is preferably set at the upper part of the heat sink 1″ and the heat sink welding zone 12″ is preferably set at the center of the lower part of the heat sink 1″. Each heat sink 1″ can be separated individually, or a plurality of heat sinks can be connected via a tie bar (not shown) according to the pitch of the array of pins 2″; Step 2 also includes:

Step 2.1. Set the chip carrier 4″ on the heat sink 1″, and attach a chip 6″ on the chip carrier 4″ by solder paste.

Step 3. Referring to FIG. 13A and FIG. 13B, fabricate the array of pins 2″, branch out a plurality sets of pin terminals 21″ respectively from the upper end and lower end of the array of pins 2″, set the pin welding zone 211″ corresponding to the heat sink welding zone 12″ on each set of pin terminals 21″, and set a plurality of pin positioning holes 22″ between two sets of pin terminals 21″. In a preferred embodiment, each set of pin terminals 21″ includes three pins and the heat sink welding zone 12″ is on the middle pin.

Step 3 also includes:

Step 3.1. Provide the jumper 212″ through extension of at least one of the pins on the set of pin terminals 21″ of the array of pins 2″;

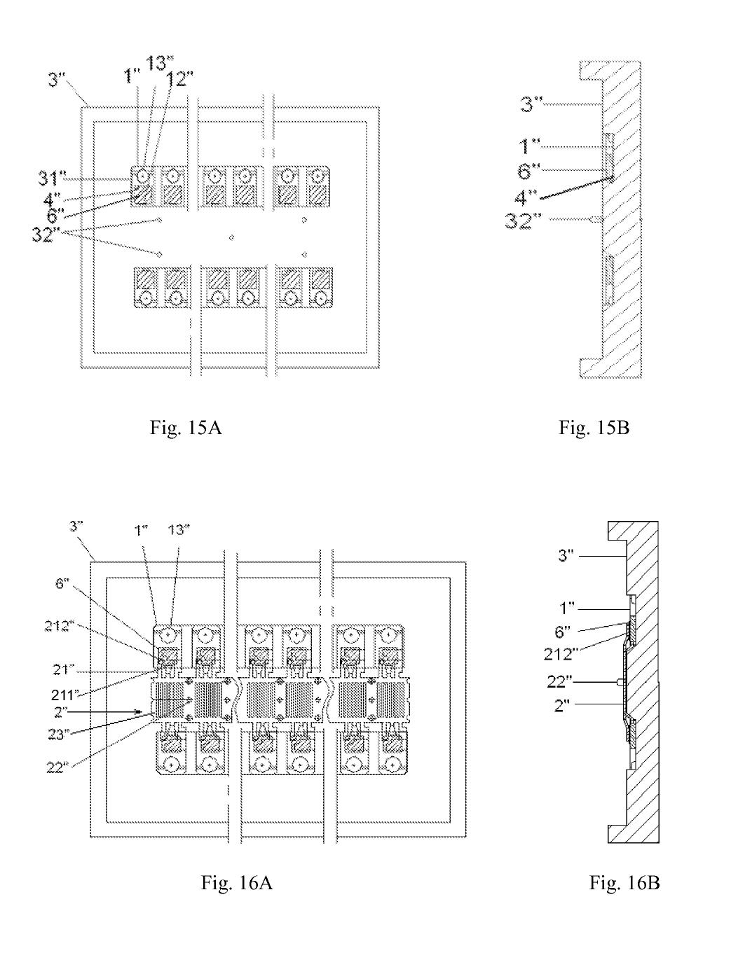

Step 4. Referring to FIG. 15A and FIG. 15B, align the heat sink positioning hole 13″ through the heat sink positioning column 311″ of the lead frame assembly welding plate 3″, so that the heat sink 1″ is positioned in the groove 31″ of the lead frame assembly welding plate 3″;

Step 5. Referring to FIG. 16A and FIG. 16B, align the pin positioning hole 22″ through the pin positioning column 32″ of the lead frame assembly welding plate 3″, so that the arrays of pin 2″ is positioned in the area between the upper and lower heat sinks 1″ on the lead frame assembly welding plate 3″;

Step 6. In Nitrogen gas or Nitrogen/Hydrogen gas mixture, apply lead-tin, tin-silver-copper or tin-bismuth solder paste to the heat sink welding zone 12″ and the pin welding zone 211″, connect the heat sink 1″ and the pin array 2″ so that the bottom surface electrode of the chip 6″ is connected with the middle pin terminal of the set of pin terminals 21″. Preferably, the welding temperature is 280-520° C., and welding duration is 5-60 seconds; Step 6 also includes:

Step 6.1. Connect the top surface electrode of the chip 6″ with other pin terminals 21″ not connected with the heat sinks via the jumper 212″.

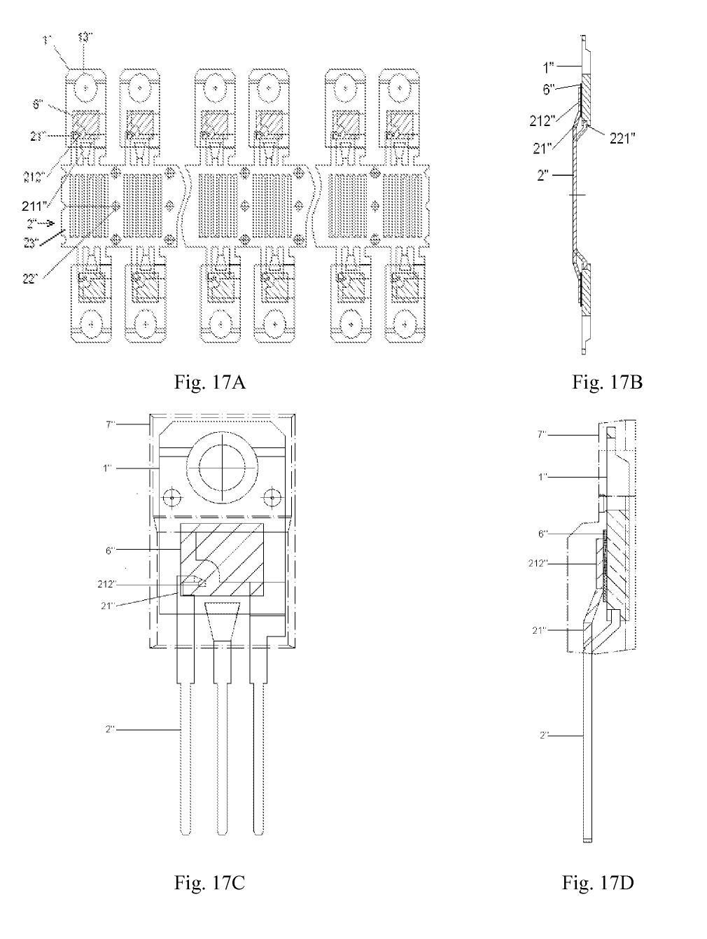

Finally, remove the connected heat sinks 1″ and arrays of pins 2″ from the lead frame assembly welding plate 3″ for cleaning and therefore obtain the mixed alloy lead frame with chip connection as shown in the attached FIG. 17A and FIG. 17B. After plastic molding, the entire packaged array is cut and separated to form individually packaged semiconductor devices as shown in FIG. 17C and FIG. 17D. Each individually packaged semiconductor device includes a power semiconductor chip (e.g. MOSFET) and a lead frame, in which the power semiconductor chip includes a plurality of top surface electrodes and a bottom surface electrode, and the lead frame includes a heat sink made of a low-cost material with good heat dissipation performance (e.g. aluminum alloy) and a plurality of pins made of a material with good conductivity (e.g. copper alloy). The heat sink further includes a chip carrier for carrying the semiconductor chip and a pin connection zone for connecting at least one pin of the plurality of pins, and the pin connection zone can be a heat sink welding zone in order to facilitate butting with a pin welding zone on the said at least one pin by means of solder. The lead frame further includes the connection with the top surface electrode of the semiconductor chip via the jumper extended from at least another pin among the plurality of pins. In FIG. 17C and FIG. 17D, plastic package 7″ is extended at least to the bottom surface of the heat sink, which can be either partially or totally exposed for better heat dissipation.

The lead frame for packaging semiconductor devices may use different materials to fabricate the heat sinks and pins respectively, which are then welded together, resulting in good heat dissipation. On the other hand, the heat sinks are independently fabricated and thick heat sinks can be obtained due to the simple process using aluminum alloy, thus saving the plastic packaging material used during the molding process, and greatly reducing the fabrication cost of power semiconductor chip packaging. By extending the jumper from the pin and connecting the chip with the pin, the wire bonding connection is eliminated and the fabrication process is simplified.

This invention provides a mixed alloy lead frame and its fabrication method for packaging power semiconductor devices, which divides the lead frame into two parts, the heat sinks and the pins. These two parts are fabricated using different material, then fixed-position welded by the designed lead frame assembly plate, thus completing the fabrication of the entire lead frame and obtaining the low-cost mixed alloy lead frame with good heat dissipation performance. In addition, this method makes it possible to not only separately fabricate the lead frame and connect the chip and lead frame, but also finish the fabrication and connection at the same time, thus improving the flexibility of actual application.

Of course, one must realize that the above introduction is the description about the optimum implementation examples of this invention, and this invention also has many modifications as long as they do not deviate from the spirit and scope of the Claims.

This invention is not only limited to the above description or the details and methods illustrated by the attached figures. It can have other implementation examples, and can be implemented in other ways. In addition, it is also realized that the expressions, terms and abstracts used here are only for illustrative, and definitely not limited to it.

For this reason, technical personnel in this field will understand that the viewpoints on which this invention is based can be used to design other structures, methods and systems in order to implement the several objectives of this invention. Therefore, it is essential that the attached Claims will be regarded as containing all these equivalent constructions, as long as they do not deviate from the spirit and scope of this invention.

1. A method of using mixed alloy lead frame for packaging power semiconductor devices comprises the following steps:
Step 1. Fabricate a lead frame assembly welding plate (3,3′,3″), set a plurality sets of upper and lower grooves (31,31′,31″) at an upper part and a lower part of the lead frame assembly welding plate (3,3′,3″) respectively, set a plurality of heat sink positioning columns (311,311′,311″) in each groove (31,31′,31″), and set a plurality of pin positioning columns (32,32′,32″) at a center of the lead frame assembly welding plate (3,3′,3″) between the upper and lower grooves;
Step 2. Fabricate a plurality of heat sinks (1,1′,1″), set a positioning hole (13,13′,13″) and a heat sink welding zone (12,12′,12″) on each heat sink (1,1′,1″);
Step 3. Fabricate a pin array (2,2′,2″), branch out a plurality of multiple-pin sets of pin terminals (21,21′,21″) respectively from an upper end and a lower end of the pin array (2,2′,2″), set a pin welding zone (211,211′,211″) corresponding to the heat sink welding zones (12,12′,12″) on a pin terminal of each set of pin terminals (21,21′,21″), and set a plurality of pin positioning holes (22,22′,22″) between two sets of pin terminals (21,21′,21″);
Step 4. Position the heat sinks (1,1′,1″) in the grooves (31,31′,31″) of the lead frame assembly welding plate (3,3′,3″) with the heat sink positioning columns (311,311′,311″) of the lead frame assembly welding plate (3,3′,3″) going through the heat sink positioning holes (13,13′,13″);
Step 5. Position the pin array (2,2′,2″) in the area between the upper and lower grooves on the lead frame assembly welding plate (3,3′,3″) with the pin positioning columns (32,32′,32″) (22,22′,22″) of the lead frame assembly welding plate (3,3′,3″) going through the pin positioning hole; and
Step 6. Connect the heat sinks (1,1″,1″) and the pins (2,2′,2″) by joining each pin welding zone to a corresponding heat sink welding zones therefore forming a lead frame array.

2. The method of claim 1, wherein Step 2 further comprises:
Step 2.1. provide a chip carrier (4, 4″) on each heat sink (1, 1″).

3. The method of claim 1, wherein Step 3 further comprises:
Step 3.1. provide a chip carrier (4′) extended from the pin welding zone (211′);
Step 3.2. Fix the chip (6′) onto the chip carrier (4′);
Step 3.3. Connect the chip (6′) to the pin terminal (21′) of the pin (2′) via bonding wire(5′).

4. The method of claim 2, wherein Step 2.1 further comprising fixing the chip (6″) on the chip carrier (4″).

5. The method of claim 4 wherein Step 3 further comprising:
Step 3.1. provide a jumper (212″) extending from one of the pin terminal (21″).

6. The method of claim 5, wherein Step 6 further comprises:
Step 6.1. Connect the chip (6″) to the one of the pin terminal (21″) via the jumper (212″).

7. The method of claim 3 wherein the pin welding zone extends to at least a portion of a bottom surface of the chip carrier.
